(19) United States
(12) Patent Application Publication
(10) Pub. No.: US 2012/0267741 A1
(43) Pub. Date: Oct. 25, 2012

(54) SOLID-STATE IMAGING DEVICE AND METHOD FOR MANUFACTURING THE SAME

(75) Inventors: SHIGERU SUZUKI, Toyama (JP); HIROFUMI OHNAKA, Toyama (JP); KOUICHI YAMAMOTO, Toyama (JP)

(73) Assignee: PANASONIC CORPORATION, Osaka (JP)

(21) Appl. No.: 13/448,452

(22) Filed: Apr. 17, 2012

(30) Foreign Application Priority Data
Apr. 21, 2011 (JP) 2011-094752

(51) Int. Cl. H01L 31/0232; H01L 31/18

(52) U.S. Cl. 257/432; 438/69; 257/E31.127

(57) ABSTRACT

A solid-state imaging device includes: a light receiving portion formed on a semiconductor substrate; a multilayer structure formed on the semiconductor substrate, that includes an interlayer insulating film and a first concave portion at a position corresponding to the light receiving portion; and an optical waveguide formed in the first concave portion. The optical waveguide includes a first film and a second film formed sequentially from a side of the multilayer structure. The first film covers a side face and a bottom face of the first concave portion and includes a second concave portion. The second film is in contact with the first film and fills up the second concave portion. The thickness of the first film formed on the side face of the first concave portion is thinner at a top portion of the first concave portion than at the bottom portion thereof.

### BACKGROUND

1. Technical Field

The present invention relates to a solid-state imaging device and a method for manufacturing the same, and in particular, to a solid-state imaging device including an optical waveguide and a method for manufacturing the same.

2. Description of the Related Art

In recent years, while pixels are miniaturized and densely packed as solid-state imaging devices are reduced in size and hence the light receiving region is reduced, there are demands for higher sensitivity. In order to achieve compatibility between a reduction in the light receiving region and higher sensitivity, various structures for allowing light to enter a light receiving element more efficiently are considered. For example, there is a structure in which an on-chip lens is provided on a color filter so that light is efficiently collected for a light receiving element. Another structure is provided with an optical waveguide on a light receiving element, so that incident light is efficiently guided to the light receiving element.

The optical waveguide for guiding incident light to the light receiving element can be formed by providing a concave portion to an interlayer insulating film formed on the light receiving element, and filling the concave portion with a material whose refractive index is higher than that of the interlayer insulating film. However, because of a reduction in the light receiving region, the aspect ratio of the concave portion for forming the optical waveguide is increased. When deposition is carried out into a concave portion whose aspect ratio is high using a vapor-state raw material, voids may be formed because of insufficient supply of the raw material into the concave portion.

As a method for forming an optical waveguide in a concave portion whose aspect ratio is high, what is known is a method of filling the concave portion with resin that can be deposited by the application process (e.g., see Unexamined Japanese Patent Publication No. 2010-283145).

### SUMMARY

However, in the case where the concave portion is filled with the resin, it is associated with a problem that the light collecting performance of the optical waveguide cannot fully be increased.

Higher refractive index of the material with which the concave portion is filled can improve the light collecting performance of the optical waveguide. However, in connection with a resin material that can be deposited by the application process, the refractive index cannot fully be increased. For example, while the refractive index of silicon nitride is approximately 1.9, the refractive index of titanium-doped siloxane polymer is just as small as approximately 1.7. Accordingly, it is difficult to form an optical waveguide whose light collecting performance is high by the conventional methods.

The present invention makes it possible to easily implement a solid-state imaging device including an optical waveguide being filled with a material whose refractive index is high, and hence possessing high light collecting performance.

The present invention provides a solid-state imaging device including an optical waveguide that is made of a layered film made up of a first film and a second film embedded in a concave portion. The thickness of the first film is thinner at the top portion of the concave portion than at the bottom portion thereof.

Specifically, a solid-state imaging device according to a first aspect of the present invention includes: a light receiving portion formed on a semiconductor substrate; a multilayer structure that is formed on the semiconductor substrate, the multilayer structure including an interlayer insulating film, and the multilayer structure including a first concave portion at a position corresponding to the light receiving portion; and an optical waveguide that is formed in the first concave portion to guide light to the light receiving portion. The optical waveguide includes a first film and a second film that are formed sequentially from the multilayer structure, the first and second films each being a single-layer film. The first film covers a side face and a bottom face of the first concave portion and includes a second concave portion at a position corresponding to the first concave portion. The second film is in contact with the first film, and the second concave portion is filled with the second film to the top end of the second concave portion. The thickness of a portion of the first film that is formed on the side face of the first concave portion is thinner at a top portion of the first concave portion than at a bottom portion of the first concave portion.

A solid-state imaging device according to a second aspect of the present invention includes: a light receiving portion that is formed on a semiconductor substrate; a multilayer structure that is formed on the semiconductor substrate, the multilayer structure including an interlayer insulating film, and the multilayer structure including a first concave portion at a position corresponding to the light receiving portion; and an optical waveguide that is formed in the first concave portion to guide light to the light receiving portion. A plurality of layers including the interlayer insulating film is exposed on the side face of the first concave portion. The optical waveguide includes a first film and a second film that are formed sequentially from a side of the multilayer structure. The first film is in contact with a plurality of the layers on the side face of the first concave portion and includes a second concave portion at a position corresponding to the first concave portion. The second film is in contact with the first film. The second concave portion is filled with the second film. The thickness of a portion of the first film that is formed on the side face of the first concave portion is thinner at a top portion of the first concave portion than at a bottom portion of the first concave portion.

In each of the solid-state imaging devices according to the first and second aspects, the optical waveguide includes the first film and the second film, and the thickness of the first film formed on the side face of the first concave portion is thinner at the top portion of the first concave portion than at the bottom portion thereof. Therefore, the second concave portion can easily be filled with the second film through any vapor deposition process such as the CVD process. Accordingly, the second film can be of a film made of a material whose refractive index is great, and an optical waveguide possessing excellent light collecting performance can be formed.

In each of the solid-state imaging devices according to the first and second aspects, a straight line that connects between a central portion in a depth direction and a bottom end portion of the portion of the first film covering the side face of the first concave portion preferably forms an angle of 75° or less with a direction being parallel to a main face of the semiconductor substrate.

In each of the solid-state imaging devices according to the first and second aspects, the first film that is formed on the side face of the first concave portion preferably has a thickness that the thickness at the top portion of the first concave portion is as small as 3/7 or less of the thickness at the bottom portion of the first concave portion.

In each of the solid-state imaging devices according to the first and second aspects, the bottom face of the first concave portion is a plane being parallel to a main face of the semiconductor substrate.

In each of the solid-state imaging devices according to the first and second aspects, the second film may be greater in refractive index than the interlayer insulating film and equal to or greater than the first film.

In each of the solid-state imaging devices according to the first and second aspects, the second film may be one of a silicon nitride film and a silicon oxynitride film.

In each of the solid-state imaging devices according to the first and second aspects, the second film may not be formed in a region of an outer region relative to the first concave portion.

In each of the solid-state imaging devices according to the first and second aspects, a top face of the first film may be formed on a plane identical to a top face of the multilayer structure.

In each of the solid-state imaging devices according to the first and second aspects, the thickness of the portion of the first film that is formed on the side face of the first concave portion may linearly increase from the top portion of the first concave portion toward the bottom portion of the first concave portion.

In each of the solid-state imaging devices according to the first and second aspects, a portion of the second film formed in the first concave portion may have its top face formed to be convex lens-shape.

A solid-state imaging device manufacturing method of the present invention includes: forming a multilayer structure that includes a first concave portion on a semiconductor substrate on which a light receiving element is formed, the first concave portion being at a position corresponding to the light receiving element; and forming an optical waveguide that is embedded in the first concave portion. The forming the optical waveguide includes forming, on the multilayer structure, a first film being a single-layer film such that a second concave portion remains at a position corresponding to the first concave portion. The forming the optical waveguide includes etching a portion of the first film that is formed on a side face of the first concave portion such that a top portion of the first concave portion becomes thinner than a bottom portion of the first concave portion. The forming the optical waveguide includes, subsequent to the etching, forming a second film being a single-layer film so as to be in contact with the first film such that the second concave portion is filled with the second film.

In the solid-state imaging device manufacturing method of the present invention, the forming the optical waveguide includes the forming the first film and the etching a portion of the first film that is formed on the side face of the first concave portion such that the top portion of the first concave portion becomes thinner than the bottom portion of the first concave portion. The forming the optical waveguide includes forming the second film such that the second concave portion is filled with the second film. Accordingly, it becomes possible to allow the thickness of the first film to be thinner at the top portion of the first concave portion than at the bottom portion of the first concave portion. This allows the second film to be deposited without inviting the occurrence of voids even in a case where the aspect ratio is great. Accordingly, an optical waveguide possessing excellent light collecting performance can easily be formed.

In the solid-state imaging device manufacturing method of the present invention, the first film and the second film may be deposited by the chemical vapor deposition process.

In the solid-state imaging device manufacturing method of the present invention, in the etching, a straight line that connects between a central portion in a depth direction and a bottom end portion of the portion of the first film that covers the side face of the first concave portion preferably forms an angle of 75° or less with a direction parallel to a main face of the semiconductor substrate.

In the solid-state imaging device manufacturing method of the present invention, in the etching, the first film that is formed on the side face of the first concave portion preferably has a thickness that the thickness at the top portion of the first concave portion is as small as 3/7 or less of the thickness at the bottom portion of the first concave portion.

In the solid-state imaging device manufacturing method of the present invention, the etching may be performed using one of nitrogen, hydrogen or fluorocarbon-base gas.

In the solid-state imaging device manufacturing method of the present invention, the forming the optical waveguide may include, subsequent to the forming the second film, processing a top face of a portion of the second film formed in the first concave portion to be convex lens-shape.

In the solid-state imaging device manufacturing method of the present invention, the processing the top face to be convex lens-shape may be polishing the second film at a rate lower than a rate at which the first film is polished.

In the solid-state imaging device manufacturing method of the present invention, the processing the top face to be convex lens-shape includes forming a sacrificial film on the second film and etching back the sacrificial film and the second film. The etching back may be performed under a condition that an etch rate of the second film is greater than an etch rate of the sacrificial film. Further, the processing the top face to be convex lens-shape may include forming a sacrificial film on the second film and etching back the sacrificial film and the second film, wherein the etching back may be performed under a condition that an etch rate of the first film is greater than the etch rate of the second film.

With the solid-state imaging device and method for manufacturing the same of the present invention, a solid-state imaging device including an optical waveguide filled with a material of high refractive index and possessing high light collecting performance can easily be implemented.

### BRIEF DESCRIPTION OF DRAWINGS

FIG. 1 is a cross-sectional view showing a solid-state imaging device according to one embodiment;

FIG. 2A is a cross-sectional view showing a solid-state imaging device manufacturing method according to one embodiment in order of steps;

FIG. 2B is a cross-sectional view showing the solid-state imaging device manufacturing method according to one embodiment in order of steps;

FIG. 3A is a cross-sectional view showing the solid-state imaging device manufacturing method according to one embodiment in order of steps;

FIG. 3B is a cross-sectional view showing the solid-state imaging device manufacturing method according to one embodiment in order of steps;

FIG. 4A is a cross-sectional view showing the solid-state imaging device manufacturing method according to one embodiment in order of steps;

FIG. 4B is a cross-sectional view showing the solid-state imaging device manufacturing method according to one embodiment in order of steps;

FIG. 5 is a cross-sectional view showing a variation of the solid-state imaging device according to one embodiment;

FIG. 6 is a graph in which the relationship between the aspect ratio of a concave portion and a void occurring in an optical waveguide is plotted;

FIG. 7 is a graph in which the relationship between a tilt angle of a portion formed on a side face of the concave portion in the first film and the void occurring in the optical waveguide is plotted;

FIG. 8 is a cross-sectional view showing a variation of the solid-state imaging device according to one embodiment;

FIG. 9 is a cross-sectional view showing a variation of the solid-state imaging device according to one embodiment;

FIG. 10 is a cross-sectional view showing a variation of the solid-state imaging device according to one embodiment;

FIG. 11 is a cross-sectional view showing a variation of the solid-state imaging device according to one embodiment;

FIG. 12 is a cross-sectional view showing a variation of the solid-state imaging device according to one embodiment;

FIG. 13 is a cross-sectional view showing a variation of the solid-state imaging device according to one embodiment; and

FIG. 14 is a cross-sectional view showing a variation of the solid-state imaging device according to one embodiment.

### DETAILED DESCRIPTION OF THE PREFERRED EMBODIMENT

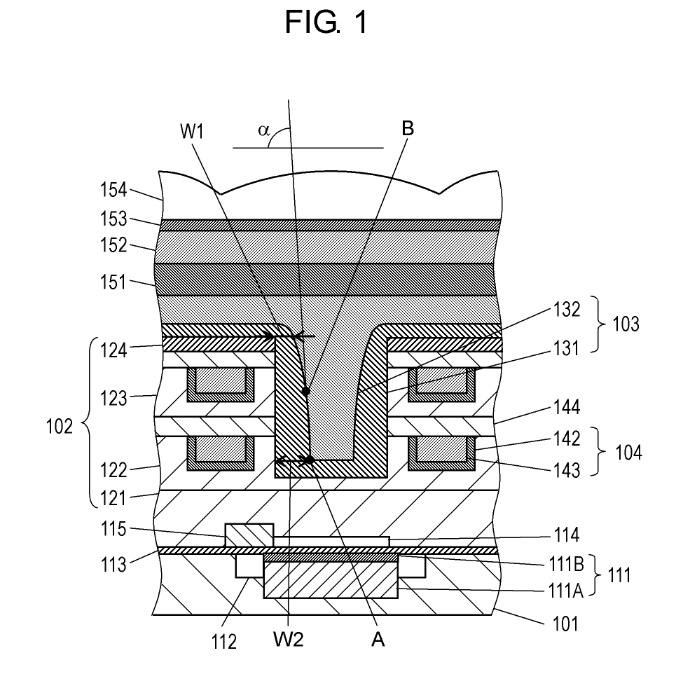

FIG. 1 shows one pixel in a solid-state imaging device according to one embodiment. As shown in FIG. 1, the solid-state imaging device of the present embodiment is a Complementary Metal Oxide Semiconductor (CMOS) sensor. A pixel including light receiving element 111 is formed on a light receiving face of substrate 101 of a silicon substrate or the like. On substrate 101, multilayer structure 102 and optical waveguide 103 embedded in multilayer structure 102 are formed.

Light receiving element 111 may be a photodiode in which a pn junction is formed by n type charge storage layer 111A and p⁺ type surface layer 111B. Beside light receiving element 111 in substrate 101, element isolation region 112 is formed. Element isolation region 112 may be formed by injecting impurities such as boron through ion injection into a prescribed region of substrate 101. On substrate 101, gate insulating film 113 made of silicon oxide (SiO₂) or the like is formed.

On gate insulating film 113, gate electrode 115 is formed adjacent to light receiving element 111. Gate electrode 115 may be a polysilicon film, a layered film made up of a polysilicon film and a silicon compound film or the like. Gate electrode 115 structures a transfer transistor that transfers signal charges and the like generated and accumulated in light receiving element 111 to a floating diffusion (not shown). On substrate 101, in addition to the transfer transistor, a plurality of transistors that structure the pixel are formed. On the top side of light receiving element 111 corresponding to gate insulating film 113, anti-reflection film 114 that prevents light entering the light receiving element 111 from being reflected from the surface of substrate 101 is formed. Anti-reflection film 114 may be a silicon nitride (SiN) film, a silicon oxynitride (SiON) film or the like.

In multilayer structure 102, a plurality of interconnections 104 are embedded, and multilayer structure 102 has a concave portion in a region corresponding to light receiving element 111. First interlayer insulating film 121 that covers gate electrode 115 and the like may be a SiO₂ film, a silicon oxycarbide (SiOC) film or the like whose thickness is approximately 400 nm.

On first interlayer insulating film 121, second interlayer insulating film 122 and third interlayer insulating film 123 are sequentially formed. Second interlayer insulating film 122 and third interlayer insulating film 123 each may be a SiO₂ film, a SiOC film or the like whose thickness is approximately 300 nm. In second interlayer insulating film 122 and third interlayer insulating film 123, interconnections 104 formed through damascene process or the like are embedded. Interconnections 104 each have copper film 143 whose thickness is approximately 200 nm and barrier metal film 142 that prevents diffusion of copper atoms, both of which are embedded in a groove formed in second interlayer insulating film 122 or third interlayer insulating film 123. Barrier metal film 142 may be made of tantalum, tantalum nitride or the like whose thickness is approximately 20 nm. On each interconnection 104, diffusion prevention film 144 that prevents diffusion of copper atoms is formed. Diffusion prevention film 144 may be a silicon carbide (SiC) film, a silicon oxycarbide (SiOC) film, a SiON film, a SiN film or the like whose thickness is approximately 50 nm. On the topmost portion of multilayer structure 102, planarization insulating film 124 made of a tetraethoxysilane (TEOS) film or the like is formed for achieving planarization.

Optical waveguide 103 is made up of first film 131 and second film 132, with which a concave portion formed above light receiving element 111 in multilayer structure 102 is filled. Though it is preferable that first film 131 is an insulating film whose refractive index is high, it is possible to employ a film whose refractive index is smaller than that of the interlayer insulating film structuring multilayer structure 102. Preferably, second film 132 is an insulating film having a highest possible refractive index, and it may be a film whose refractive index is at least higher than the interlayer insulating film structuring multilayer structure 102, and a film whose refractive index is higher than that of first film 131. As the interlayer insulating film, normally a SiO₂ film whose refractive index is approximately 1.4 to 1.5 or a SiOC film whose refractive index is 1.5 to 1.6 is used. Accordingly, it is preferable that first film 131 and second film 132 are each a SiN film whose refractive index is approximately 1.9 to 2.0, a silicon oxynitride (SiON) film whose refractive index is approximately 1.6 to 1.8 or the like. First film 131 and second film 132 may be formed using different materials. For example, second film 132 may be a SiN film, while the first film 131 may be a SiON film. Further, first film 131 may be a SiOC film, a SiO₂ film or the like.

In connection with the part of first film 131 formed on the side face of the concave portion, thickness W1 at the top portion of the concave portion is smaller than thickness W2 at the bottom portion of the concave portion. Accordingly, the concave portion can easily be filled with second film 132 through vapor deposition or the like. In the present embodiment, light receiving element 111 has a width of approximately 700 nm, while the concave portion has a width of approximately 1000 nm and a depth of approximately 600 nm. In this case, thickness W1 of first film 131 at the top portion of the concave portion may be approximately 200 nm, and thickness W2 at the bottom portion of the concave portion may be approximately 400 nm.

On second film 132, planarization resin film 151, color filter 152, planarization film 153 and microlens 154 are sequentially formed. Planarization resin film 151 is formed for improving the flatness of the top face of second film 132 and for improving adhesiveness of color filter 152. However, it can be dispensed with when second film 132 is flat enough. Though color filter 152 is shown for only one color in FIG. 1, filters of red (R), green (G) and blue (B) are provided in the Bayer arrangement. The arrangement of the color filters may be any arrangement other than the Bayer arrangement. Further, complementary-base filters may be employed. Planarization film 153 is provided to reduce the height difference between color filters 152 of different colors. Microlens 154 is provided for improving the light collecting performance relative to the light receiving element 111.

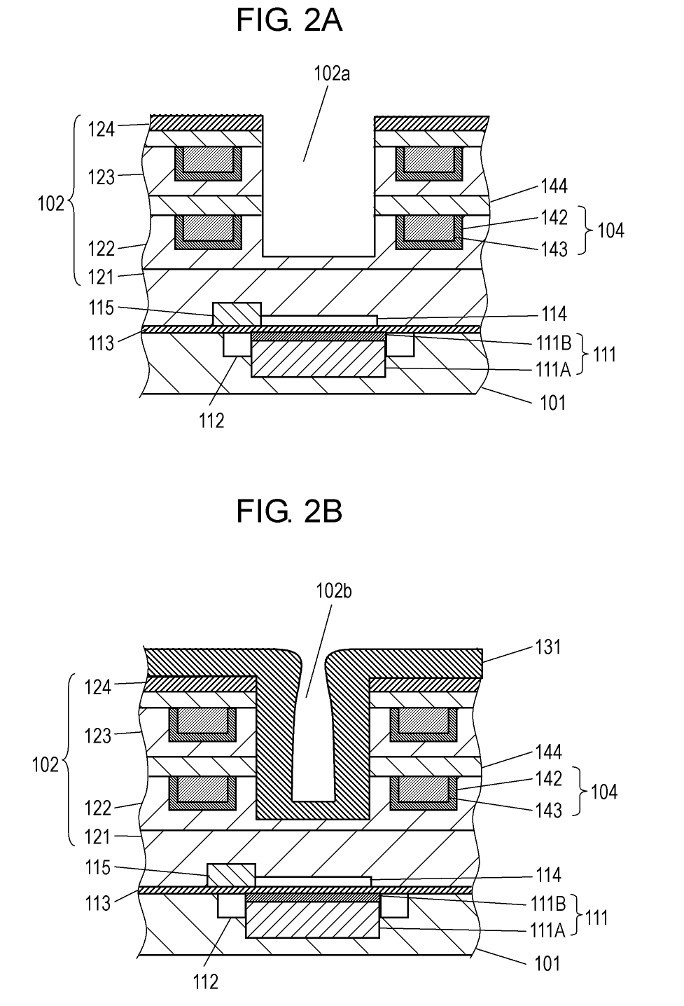

In the following, a description will be given of a method for forming optical waveguide 103. On substrate 101 on which light receiving element 111 and the like are formed, multilayer structure 102 in which interconnections 104 are embedded is formed by a known method. Thereafter, as shown in FIG. 2A, concave portion 102a is formed above light receiving element 111 in multilayer structure 102. In FIG. 2A, though concave portion 102a does not reach first interlayer insulating film 121, concave portion 102a may reach first interlayer insulating film 121. Further, the bottom face of concave portion 102a is preferably a plane parallel to the main face of substrate 101. The width and the depth of concave portion 102a should be determined taking into consideration of the two-dimensional dimension of light receiving element 111, the light collecting performance and the like in the case where microlens 154 and optical waveguide 103 are combined with each other. In the present embodiment, the description will be given based on that the width of the concave portion 102a is 1000 nm and the depth thereof is 600 nm (i.e., the aspect ratio is 0.6).

Next, as shown in FIG. 2B, first film 131 made of SiN or the like is formed using the chemical vapor deposition process (CVD process) or the like. In the case where SiN film or the like is deposited by the CVD process, the thickness becomes greater at the top portion of concave portion 102a than at the bottom portion thereof, and an overhung portion is formed. When the overhung portion closes concave portion 102a, it becomes difficult for concave portion 102a to be filled with second film 132. Therefore, first film 131 is formed such that the top portion of concave portion 102a is not closed and concave portion 102b remains at the position corresponding to concave portion 102a. In order for the top portion of concave portion 102a not to be closed, the thickness of the region in multilayer structure 102 except for concave portion 102a (i.e., the flat portion) is preferably 60% or less as small as the width of concave portion 102a. In the present embodiment, a description is given of an example where the thickness of the flat portion of multilayer structure 102 is 500 nm.

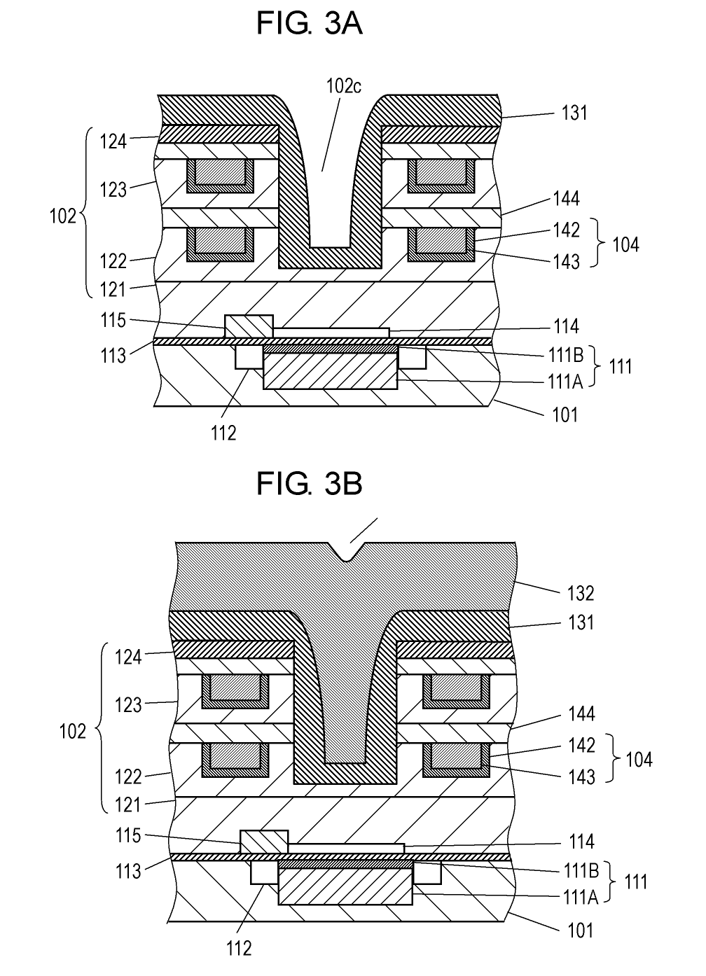

Next, as shown in FIG. 3A, etch back using the dry etching process is performed to thereby remove the overhung portion. Thus, the thickness of first film 131 becomes thinner at the top portion of concave portion 102a than at the bottom portion thereof. Accordingly, concave portion 102c whose width is wider at the top end portion than at the bottom face is formed. In the present embodiment, when the etch back amount at the flat portion is approximately 300 nm, the overhung portion is removed, and the thickness of concave portion 102a can be made thinner at the top portion than at the bottom portion. Thus, thickness W1 of first film 131 at the top portion of concave portion 102a becomes approximately 150 nm, and thickness W2 at the bottom portion becomes approximately 350 nm. When thickness W1 is as small as 3/7 or less of thickness W2, occurrence of a void can be prevented even in the case where the aspect ratio is approximately 0.6.

Next, as shown in FIG. 3B, second film 132 made of SiN or the like is deposited using the CVD process or the like, such that concave portion 102c is filled therewith. On the top face of second film 132, recess 132a is produced at the position corresponding to concave portion 102c.

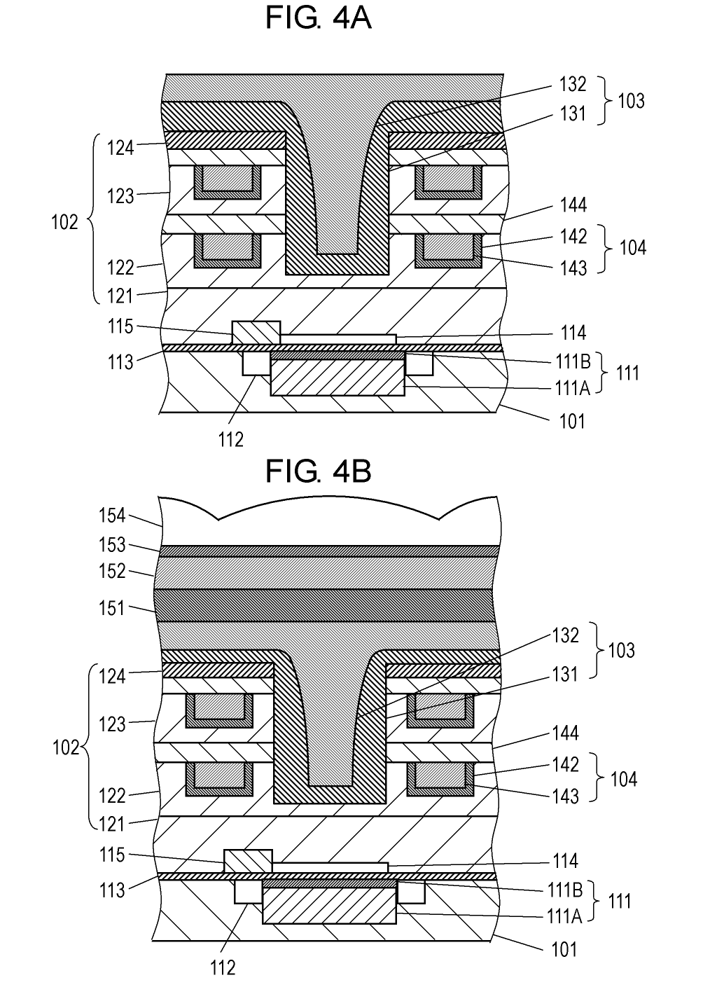

Next, as shown in FIG. 4A, using the chemical mechanical polishing process (CMP process) or the like, the top face of second film 132 is polished to be planarized.

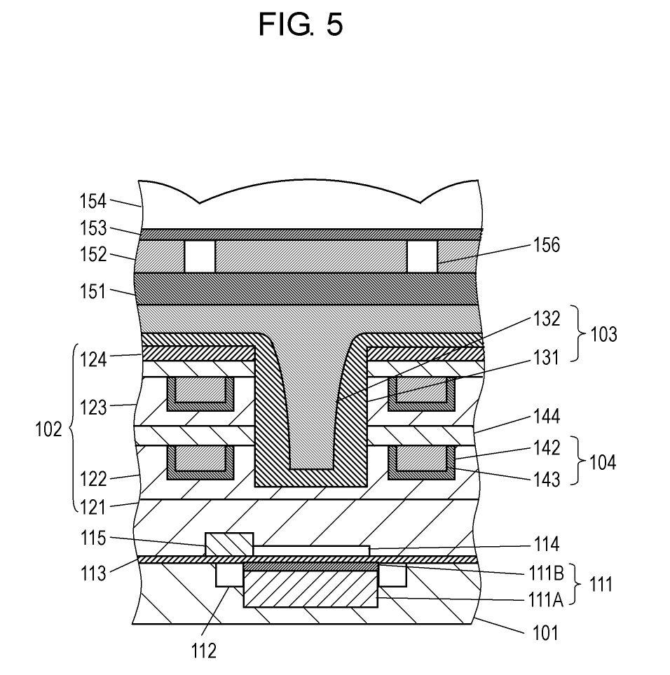

Next, as shown in FIG. 4B, planarization resin film 151, color filter 152, planarization film 153, and microlens 154 are sequentially formed. It is to be noted that, in the present embodiment, the structure in which color filter 152 is continuously formed has been shown. However, as shown in FIG. 5, insulating film 156 for isolation may be formed between color filters 152. Allowing a material whose refractive index is lower than that of color filter 152 to surround the color filter, the light collecting performance of color filter 152 can be improved. Since the refractive index of a general color filter is approximately 1.5 to 1.7, insulating film 156 should be a TEOS film (refractive index 1.45) or the like whose refractive index is lower than that.

In the present embodiment, concave portion 102a is filled with first film 131 and second film 132 being sequentially formed. Further, after first film 131 is formed, etch back is performed, such that thickness W1 at the top portion of concave portion 102a becomes smaller than thickness W2 at the bottom portion thereof. Thus, when second film 132 is deposited, a gaseous raw material is fully supplied into concave portion 102a. Accordingly, even in a case where a film made of a material whose refractive index is high is formed using the CVD process or the like, a void is not easily occur in second film 132 inside concave portion 102a. As a result, the optical waveguide whose refractive index is high and possessing excellent light collecting performance can efficiently be formed.

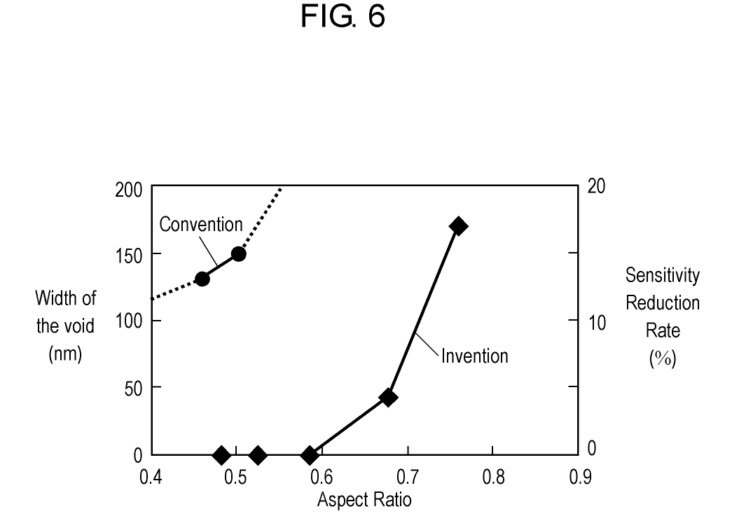

FIG. 6 shows the relationship between the aspect ratio of the concave portion and the width of the void occurring in the optical waveguide. The width of the void is the maximum value in the direction parallel to the main face of the substrate. The sensitivity reduction rate in the second vertical axis is theoretically calculated from the width of the void. As to the optical waveguide used for evaluation, a SiN film is formed by the CVD process. Further, the thickness of the first film at the top portion of the concave portion is as small as 3/7 or less of the thickness of the first film at the bottom portion of the concave portion.

With the conventional optical waveguide which is formed by the concave portion being filled with the insulating films at once, a large void occurs even when the aspect ratio is small, and a reduction in sensitivity incurred by the void is inevitable.

On the other hand, with the optical waveguide according to the present embodiment, which is formed by forming the first film whose thickness at the top portion of the concave portion is smaller than at the bottom portion thereof, and thereafter filling the concave portion with the second film, no void occurs until the aspect ratio becomes as great as approximately 0.6. Thus, in the present embodiment, even in the case where the aspect ratio is great, it is possible to form an optical waveguide possessing high light collecting performance using a material whose refractive index is high. Thus, a solid-state imaging device possessing excellent light collecting performance can be implemented.

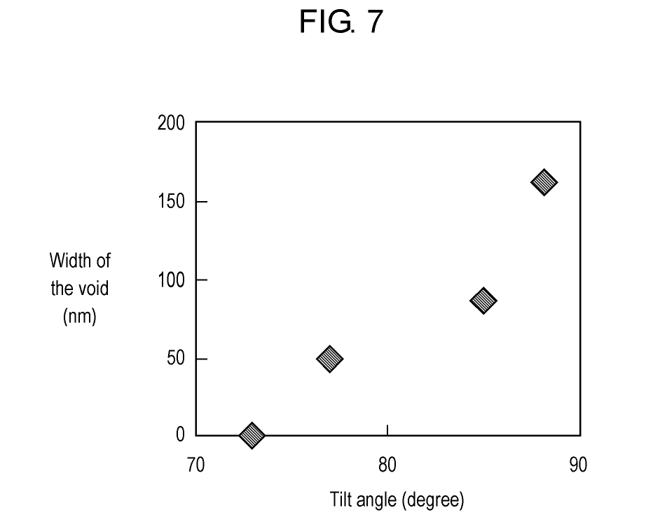

FIG. 7 shows the relationship between tilt angle α and the void width of the portion of first film 131 formed on the side face of concave portion 102a. Tilt angle α shown in FIG. 7 represents angle α formed between a straight line connecting between the bottom end portion denoted by symbol A in FIG. 1 and the central portion in the depth direction denoted by symbol B and the direction parallel to the main face of substrate 101 (i.e., the horizontal direction). The aspect ratio of concave portion 102a used for evaluation is 0.6. As shown in FIG. 7, setting tilt angle α of first film 131 to be 75° or less can suppress occurrence of a void in the optical waveguide 103. It is to be noted that, tilt angle α can be adjusted by changing the ratio between monofluoromethane (CH₃F) and oxygen (O₂) when etch back is performed using CH₃F and O₂, for example.

An optical waveguide filled with second film 132 made of SiN whose refractive index is approximately 1.93 by the CVD process and an optical waveguide filled with titanium-doped siloxane polymer whose refractive index is approximately 1.75 by the application process are actually prepared and compared against each other. In the case where the SiN film is used, the amount of light entering light receiving element 111 is improved by at least 10% as compared to the case where titanium-doped siloxane polymer is used. Thus, with the solid-state imaging device according to the present embodiment, it is possible for the optical waveguide to be filled with a material whose refractive index is high, such as SiN, without inviting the occurrence of a void. Hence, the present embodiment is useful in improving the light collecting performance.

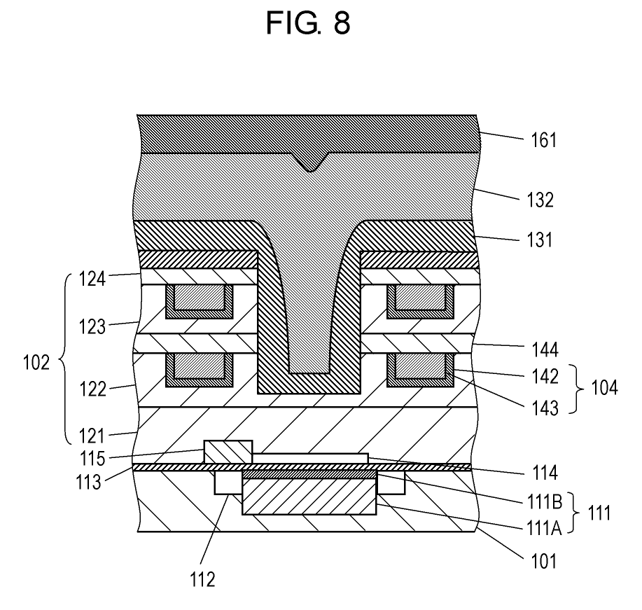

In the present embodiment, the description has been given of the method of polishing second film 132 by CMP process or the like to be planarized. However, as shown in FIG. 8, the following manner is also possible: forming sacrificial film 161 for planarization made of applied film on second film 132; and thereafter etching sacrificial film 161 and second film 132, to planarize second film 132. As sacrificial film 161, a resist film, a spin-on glass (SOG) film or the like may be used.

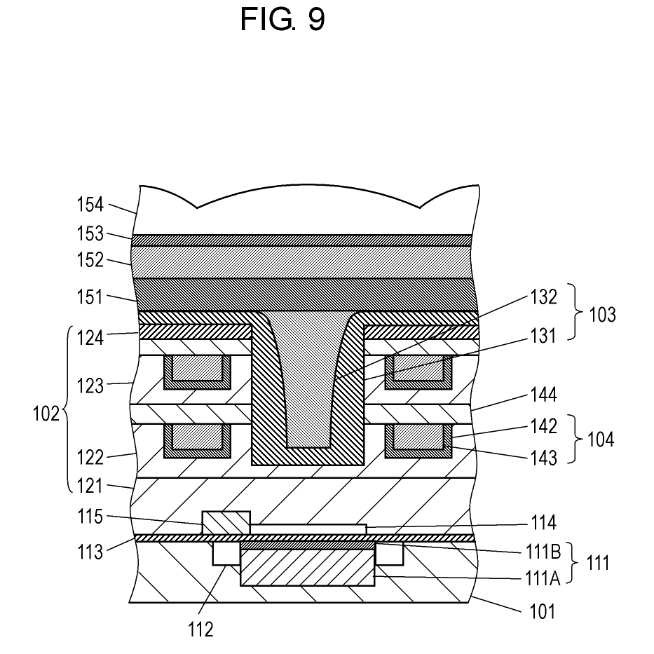

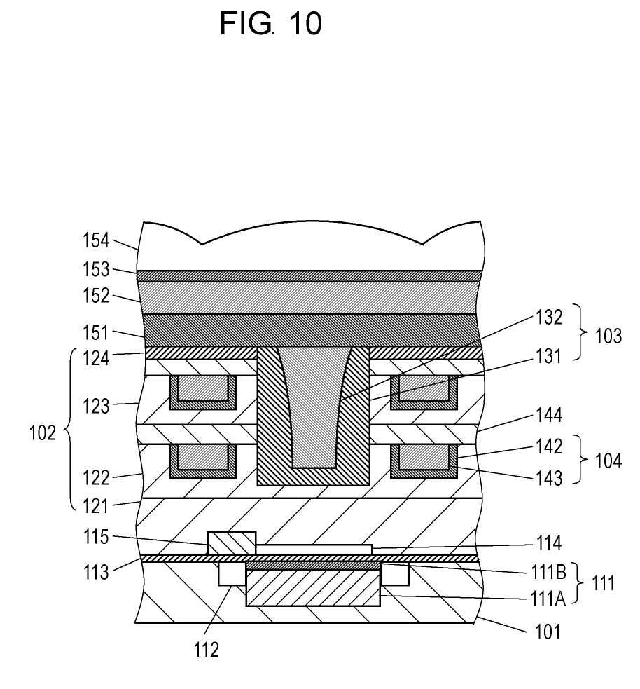

The light collecting performance of optical waveguide 103 is affected by the length (depth) of optical waveguide 103 in the direction perpendicular to the main face of substrate 101. Accordingly, the polishing amount when second film 132 is planarized should be adjusted such that a depth at which the maximum light collecting performance can be secured as being combined with microlens 154. As necessary, as shown in FIG. 9, the portion of second film 132 formed on the flat portion may be removed. Further, as shown in FIG. 10, the portion of first film 131 formed on the flat portion may also be removed. While FIG. 10 shows an example where the portion of first film 131 formed on the flat portion is fully removed, first film 131 may remain on the flat portion of multilayer structure 102 by a prescribed thickness. Removal of the portion of second film 132 and the portion of first film 131 which are formed in the region except for concave portion 102a provides an added effect of preventing leakage of light to the outside of concave portion 102a through second film 132 and first film 131.

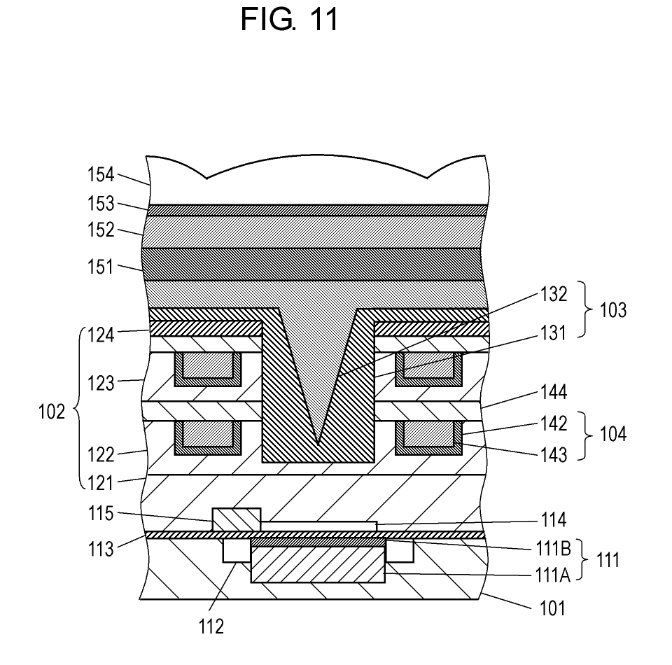

In the present embodiment, what has been shown is the example in which concave portion 102c that remains after first film 131 is formed has a flat bottom face. However, the requirement is just that the thickness of the portion of first film 131 formed at the top portion of concave portion 102a is greater than the thickness of that formed at the bottom portion, and it is not necessary for the bottom face to be formed flat. For example, as shown in FIG. 11, first film 131 may be formed such that a concave portion whose cross section is V-shaped remains. Such a remaining concave portion whose cross section is V-shaped can further increase tilt angle α of the portion of first film 131 formed on the side face of the concave portion, which advantageously facilitates the concave portion to be filled with second film 132.

For increasing tilt angle α, first film 131 should be deposited to be thicker using any gas exhibiting high deposition performance, such as nitrogen (N₂), hydrogen (H₂), fluorocarbon-base gas or the like, and etched. As the fluorocarbon-base gas, a gas whose general formula is expressed as CHₓF_{y} can be used. Though it is also possible to use carbon tetrafluoride not containing H (x=0) as the fluorocarbon-base gas, greater x contributes toward greater deposition performance and, therefore, it is preferable to use CH₃F, CHF₃ or the like. Use of a gas exhibiting great deposition performance in etching may cause etch stop. Addition of oxygen (O₂) or the like can suppress occurrence of etch stop. For example, in the case where fluorocarbon-base gas expressed as CHₓF_{y} is used, H and F separates, whereby CHₓ₂F_{y2} having dangling bonds is generated, and polymerization occurs among CHₓ₂F_{y2}. In connection with separation of H and F, a greater increase in electric power applied for decomposing the etching gas accelerates decomposition of the gas. Therefore, a further increase in electric power in a range where etch stop does not occur allows the polymer film to be formed thicker, whereby the width at the bottom portion of the concave portion can be narrowed. Further, the greater the pressure of the gas, the smaller the directivity of ions in plasma, whereby the rate of disappearance of the polymer film becomes smaller than that of generation of the polymer film. Therefore, a higher gas pressure in a range where etch stop does not occur increases the thickness of the polymer film, which makes it possible to further increase tilt angle α.

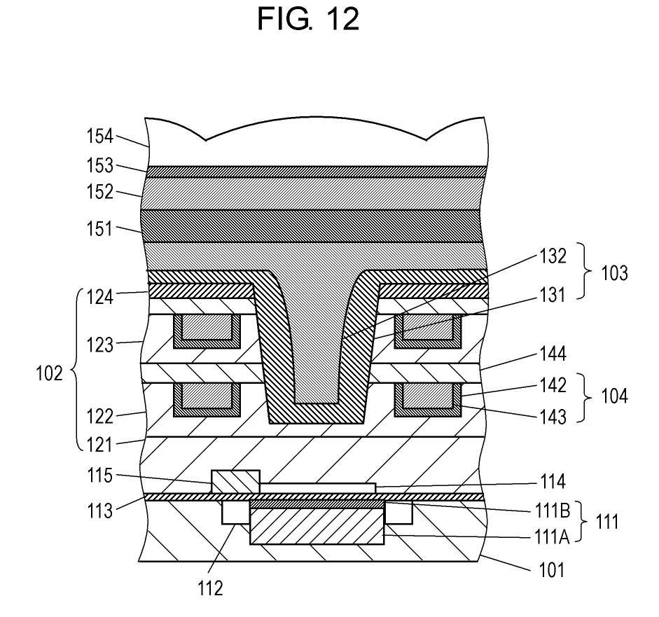

Further, the side face of concave portion 102a formed in multilayer structure 102 is not necessarily perpendicular to the main face of substrate 101. As shown in FIG. 12, it may be in a shape where the width of the top end portion is wider than the width of the bottom end portion. A greater tilt of the side face of the concave portion 102a further facilitates the optical waveguide 103 to be filled. On the other hand, an attempt to increase the extent of tilt of the side face of concave portion 102a may impair the flatness of the bottom face, which may hinder light from entering light receiving element 111. Further, multilayer structure 102 is a layered structure made up of a plurality of films being different in material from one another, and it is difficult to increase the extent of tilt of the side face of the concave portion. However, an increase in the extent of tilt of the side face of the concave portion of multilayer structure 102 in a range where the flatness of the bottom face is not impaired provides an advantage in that optical waveguide 103 can more easily be filled.

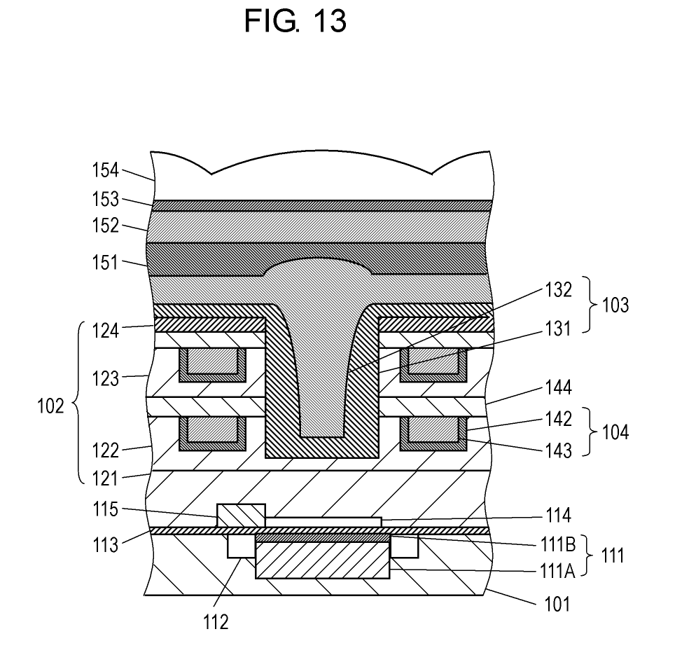

In the present embodiment, an example of planarizing the top face of second film 132 has been shown. However, as shown in FIG. 13, the top face of the portion of second film 132 formed in the concave portion may be processed to be convex lens-shape. Forming the top face of second film 132 to be convex lens-shape, the light collecting performance relative to light receiving element 111 can further be improved.

In the case where the top face of second film 132 is processed to be convex lens-shape, as shown in FIG. 8, after sacrificial film 161 is formed on second film 132, sacrificial film 161 and second film 132 may be etched to be in such form. In the case where the top face of second film 132 is processed to be convex lens-shape, sacrificial film 161 and second film 132 should entirely be etched under the condition that second film 132 becomes greater in etch rate than sacrificial film 161, and sacrificial film 161 should entirely be removed. Sacrificial film 161 should be a resist film, a SOG film or the like, and the thickness should be approximately 800 nm. Further, etching under the condition that first film 131 becomes greater in etch rate than second film 132 can also process the top face of second film 132 to be convex lens-shape. Further, depositing second film 132 as shown in FIG. 3B without forming sacrificial film 161 such that concave portion 102c is filled with second film 132, and thereafter etching under the condition that first film 131 becomes greater in etch rate than second film 132 can also form the top face of second film 132 to be a convex lens-shape.

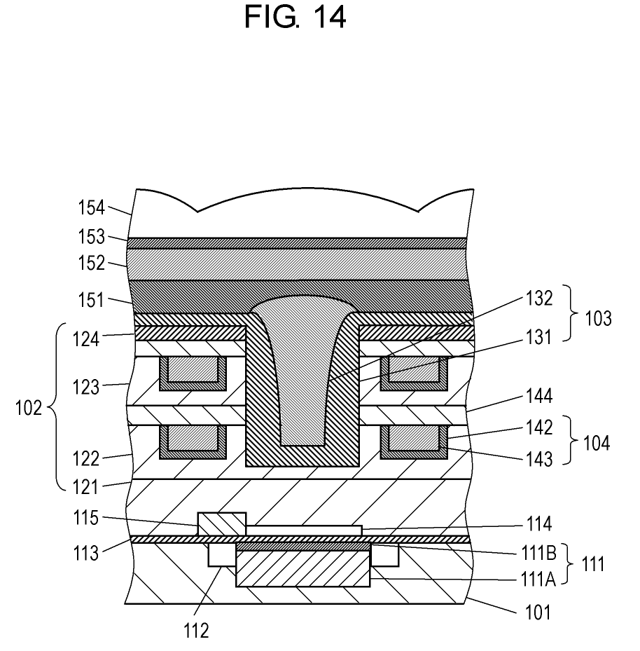

Further, as shown in FIG. 14, etching may be performed until the structure in which the portion of second film 132 formed on the flat portion of multilayer structure 102 is removed is obtained. Further, in FIG. 14, while the example in which first film 131 remains on the flat portion of multilayer structure 102 is shown, the portion of first film 131 formed on the flat portion of multilayer structure 102 may completely be removed.

Also in the case where the top face of the second film to be convex lens-shape, the tapered angle of the concave portion that remains after the first film is deposited can be made smaller. Further, it is possible to employ a structure in which the side face of the concave portion formed in the multilayer structure is tilted. Further, it is also possible to employ a structure in which the color filters are separated from each other by an insulating film.

In the present embodiment, the example in which the multilayer structure includes the interconnections of the two layers has been shown. However, the interconnections of three or more layers may be formed.

In the present embodiment, while the example in which the optical waveguide is formed by the concave portion being filled with the first film and the second film has been shown, it is also possible to employ a structure in which deposition and etching of a film to the concave portion is repetitively performed twice or more, such that the concave portion is filled with three or more films. While the example in which the CVD process is used in depositing the first film and the second film has been shown, the physical vapor deposition (PVD) process or the like can be used.

In the present embodiment, while the description has been given of the MOS-type solid-state imaging device, the present invention is applicable also to a CCD (Charge Coupled Device) type solid-state imaging device.

The solid-state imaging device and method for manufacturing the same according to the present invention can easily implement a solid-state imaging device including an optical waveguide filled with a material whose refractive index is high, and hence possessing high light collecting performance. Therefore, the present invention is useful for a solid-state imaging device being small in size and highly sensitive and a method for manufacturing the same.

What is claimed is:

1. A solid-state imaging device, comprising:
a light receiving portion formed on a semiconductor substrate;
a multilayer structure that is formed on the semiconductor substrate, the multilayer structure including a plurality of insulating films, and the multilayer structure including a first concave portion at a position corresponding to the light receiving portion; and
an optical waveguide that is formed in the first concave portion to guide light to the light receiving portion, wherein
the optical waveguide includes a first film and a second film that are formed sequentially from the multilayer structure,
the first film and the second film are each higher than the interlayer insulating film in a refractive index,
the first film covers a side face and a bottom face of the first concave portion and includes a second concave portion at a position corresponding to the first concave portion,
the second film is formed such that an inside of the second concave portion is filled with the second film, and
a thickness of a portion of the first film that is formed on the side face of the first concave portion is thinner at a top portion of the first concave portion than at a bottom portion of the first concave portion.

2. The solid-state imaging device according to claim 1, wherein
a plurality of layers including the interlayer insulating film are exposed on the side face of the first concave portion, and
the first film is in contact with a plurality of the layers on the side face of the first concave portion.

3. The solid-state imaging device according to claim 1, wherein
the second film is formed to be in contact with the first film, and
the second concave portion is filled with the second film to a top end of the second concave portion.

4. The solid-state imaging device according to claim 1, wherein
the first film and the second film are each a single-layer film.

5. The solid-state imaging device according to claim 1, wherein
the first film is one of a silicon nitride film and a silicon oxynitride film.

6. The solid-state imaging device according to claim 1, wherein
the second film is one of a silicon nitride film and a silicon oxynitride film.

7. The solid-state imaging device according to claim 1, wherein
a straight line that connects between a central portion in a depth direction and a bottom end portion of the portion of the first film that is formed on the side face of the first concave portion forms an angle of 75° or less with a direction being parallel to a main face of the semiconductor substrate.

8. The solid-state imaging device according to claim 1, wherein
the thickness of the portion of the first film that is formed on the side face of the first concave portion has a ratio of 3:7 or less between the thickness at the top portion of the first concave portion and the thickness at the bottom portion of the first concave portion.

9. The solid-state imaging device according to claim 1, wherein
the bottom face of the first concave portion is a plane being parallel to a main face of the semiconductor substrate.

10. The solid-state imaging device according to claim 1, wherein
the second film is higher than the first film in the refractive index.

11. The solid-state imaging device according to claim 1, wherein
the second film is not formed in a region of an outer region relative to the first concave portion.

12. The solid-state imaging device according to claim 1, wherein
a top face of the first film is formed on a plane identical to a top face of the multilayer structure.

13. The solid-state imaging device according to claim 1, wherein
the thickness of the portion of the first film that is formed on the side face of the first concave portion linearly increases from the top portion of the first concave portion toward the bottom portion of the first concave portion.

14. The solid-state imaging device according to claim 1, wherein
a portion of the second film formed in the first concave portion has its top face formed to be convex lens-shape.

15. A solid-state imaging device manufacturing method, comprising:
forming a multilayer structure that includes a first concave portion on a semiconductor substrate on which a light receiving element is formed, the first concave portion being at a position corresponding to the light receiving element; and
forming an optical waveguide that is embedded in the first concave portion, wherein
the forming the optical waveguide includes
forming, on the multilayer structure, a first film that is higher than the multilayer structure in a refractive index such that a second concave portion remains at a position corresponding to the first concave portion,
etching a portion of the first film that is formed on a side face of the first concave portion such that a top portion of the first concave portion becomes thinner than a bottom portion of the first concave portion, and
subsequent to the etching, forming a second film being higher than the multilayer structure in a refractive index on the first film such that the second concave portion is filled with the second film.

16. The solid-state imaging device manufacturing method according to claim 15, wherein
the second film is formed so as to be in contact with the first film and such that the second concave portion is filled with the second film to a top end of the second concave portion.

17. The solid-state imaging device manufacturing method according to claim 15, wherein
forming the optical waveguide includes, subsequent to the forming the second film, processing a top face of a portion of the second film formed in the first concave portion to be convex lens-shape.

18. The solid-state imaging device manufacturing method according to claim 17, wherein
the processing the top face to be convex lens-shape is polishing the second film at a rate lower than a rate at which the first film is polished.

19. The solid-state imaging device manufacturing method according to claim 17, wherein
the processing the top face to be convex lens-shape includes forming a sacrificial film on the second film and etching back the sacrificial film and the second film, wherein
the etching back is performed under a condition that an etch rate of the second film is greater than an etch rate of the sacrificial film.

20. The solid-state imaging device manufacturing method according to claim 17, wherein
the processing the top face to be convex lens-shape includes forming a sacrificial film on the second film and etching back the sacrificial film and the second film, wherein
the etching back is performed under a condition that an etch rate of the first film is greater than an etch rate of the second film.
